(19) United States
(12) Patent Application Publication
(10) Pub. No.: US 2025/0221224 A1
(43) Pub. Date: Jul. 3, 2025

(54) Electroluminescent Display Device

(71) Applicant: LG Display Co., Ltd., Seoul (KR)

(72) Inventors: AhnKi Kim, Paju-si (KR); Hyeonjeong Shin, Paju-si (KR); Junho Nam, Paju-si (KR)

(21) Appl. No.: 18/807,824

(22) Filed: Aug. 16, 2024

(30) Foreign Application Priority Data
Dec. 28, 2023 (KR) 10-2023-0194541

(51) Int. Cl. H10K 59/38; H10K 59/80

(52) U.S. Cl. CPC H10K 59/38; H10K 59/80517

(57) ABSTRACT

An electroluminescent display apparatus comprises a first sub-pixel including a first light emitting area, a first electrode in the first subpixel, a light emitting layer on the first electrode, a second electrode on the light emitting layer, an encapsulation layer on the second electrode, and a cyan color filter on the encapsulation layer, wherein the first light emitting area includes a first sub-light emitting area and a second sub-light emitting area, the cyan color filter includes a first sub-color filter corresponding to the first sub-light emitting area and a second sub-color filter corresponding to the second sub-light emitting area, and the first sub-color filter transmits a green light, and the second sub-color filter transmits a blue light.

### CROSS-REFERENCE TO RELATED APPLICATION

This application claims the priority of Republic of Korea Patent Application No. 10-2023-0194541 filed on Dec. 28, 2023, which is hereby incorporated by reference in its entirety.

### BACKGROUND

### Field

The present disclosure relates to an electroluminescent display device.

### Description of the Related Art

An electroluminescent display device includes a first electrode, a second electrode, and a light emitting layer disposed between the first electrode and the second electrode, and displays an image by emitting light from the light emitting layer by an electric field between the two electrodes.

Such an electroluminescent display device may include a red sub-pixel, a green sub-pixel, and a blue sub-pixel to display images of various colors.

However, there is a limit to a color reproducibility of the electroluminescent display device with only the above three sub-pixels.

### SUMMARY

The present disclosure has been made in view of the above problems and it is an object of the present disclosure to provide an electroluminescent display device capable of improving color reproducibility.

In accordance with one or more embodiments of the present disclosure, the above and other objects can be accomplished by the provision of an electroluminescent display device comprising a first subpixel including a first light emitting area, a first electrode in the first subpixel, a light emitting layer on the first electrode, a second electrode on the light emitting layer, an encapsulation layer on the second electrode, and a cyan color filter on the encapsulation layer, wherein the first light emitting area includes a first sub-light emitting area and a second sub-light emitting area, the cyan color filter includes a first sub-color filter corresponding to the first sub-light emitting area and a second sub-color filter corresponding to the second sub-light emitting area, and the first sub-color filter transmits a green light, and the second sub-color filter transmits a blue light.

In addition, in accordance with one or more embodiments of the present disclosure, the above and other objects can be accomplished by the provision of an electroluminescent display device comprising a plurality of subpixels including a first sub-pixel having a first light emitting area and a second sub-pixel having a second light emitting area, a first electrode in each of the first subpixel and the second subpixel, a light emitting layer on the first electrode in each of the first subpixel and the second subpixel, a second electrode on the light emitting layer, and a plurality of color filters including a first color filter corresponding to the first light emitting area and a second color filter corresponding to the second light emitting area, wherein the first light emitting area includes a first sub-light emitting area and a second sub-light emitting area, the first sub-light emitting area and the second sub-light emitting area emitting light of different colors, and the first color filter includes a first sub-color filter corresponding to the first light emitting area and a second sub-color filter corresponding to the second light emitting area.

### BRIEF DESCRIPTION OF THE DRAWINGS

FIG. 1 is a schematic plan view of an electroluminescent display device according to one or more embodiments of the present disclosure.

FIGS. 2 to 5 are schematic plan views of a first light emitting area emitting cyan-colored light according to one or more embodiments of the present disclosure.

FIG. 6 is a partial cross-sectional view of a first light emitting area emitting cyan light according to one or more embodiments of the present disclosure.

FIG. 7 is a partial cross-sectional view of a second light emitting area emitting blue light according to one or more embodiments of the present disclosure.

FIG. 8 is a schematic cross-sectional view of an electroluminescent display device according to one or more embodiments of the present disclosure.

FIG. 9 is a graph showing color reproducibility according to one or more embodiments of the present disclosure.

FIG. 10 is a graph showing a change in color reproducibility by changing a ratio of an area of the first sub-light emitting area to an area of the second sub-light emitting area while maintaining a ratio of a first thickness of the first sub-color filter to a second thickness of the second sub-color filter of blue as 1:1 according to one or more embodiments of the present disclosure.

FIG. 11 is a graph showing a change in color reproducibility by changing a ratio of an area of the first sub-light emitting area to an area of the second sub-light emitting area while maintaining a ratio of a first thickness of the first sub-color filter to a second thickness of the second sub-color filter as 2:1 according to one or more embodiments of the present disclosure.

FIG. 12A shows an optical spectrum for each wavelength when a general first electrode is applied according to one or more embodiments of the present disclosure.

FIG. 12B shows an optical spectrum for each wavelength when a low-reflection first electrode using a first sub-metal layer having a high deposition rate of 3.5 Å/s is applied according to one or more embodiments of the present disclosure.

FIG. 12C shows an optical spectrum for each wavelength when a low-reflection first electrode using a second sub-metal layer having a low deposition rate of 1.75 Å/s is applied according to one or more embodiments of the present disclosure.

FIG. 13A shows an optical spectrum in which a green color filter is applied to the optical spectrum of FIG. 12A according to one or more embodiments of the present disclosure.

FIG. 13B shows an optical spectrum in which a green color filter is applied to the optical spectrum of FIG. 12B according to one or more embodiments of the present disclosure.

FIG. 13C shows an optical spectrum in which a green color filter is applied to the optical spectrum of FIG. 12C according to one or more embodiments of the present disclosure.

FIG. 14A shows an optical spectrum in which a blue color filter is applied to the optical spectrum of FIG. 12A according to one or more embodiments of the present disclosure.

FIG. 14B shows an optical spectrum in which a blue color filter is applied to the optical spectrum of FIG. 12B according to one or more embodiments of the present disclosure.

FIG. 14C shows an optical spectrum in which a blue color filter is applied to the optical spectrum of FIG. 12C according to one or more embodiments of the present disclosure.

FIG. 15A is a graph showing changes in refractive index n for each wavelength band of a first sub-metal layer having a relatively high deposition rate of 3.5 Å/s and a second sub-metal layer having a relatively low deposition rate of 1.75 Å/s according to one or more embodiments of the present disclosure.

FIG. 15B is a graph showing changes in refractive index k for each wavelength band of a first sub-metal layer having a relatively high deposition rate of 3.5 Å/s and a second sub-metal layer having a relatively low deposition rate of 1.75 Å/s according to one or more embodiments of the present disclosure.

FIG. 15C is a graph showing changes in reflectance for each wavelength band of a first sub-metal layer having a relatively high deposition rate of 3.5 Å/s and a second sub-metal layer having a relatively low deposition rate of 1.75 Å/s according to one or more embodiments of the present disclosure.

FIG. 15D is a graph showing changes in transmittance for each wavelength band of a first sub-metal layer having a relatively high deposition rate of 3.5 Å/s and a second sub-metal layer having a relatively low deposition rate of 1.75 Å/s according to one or more embodiments of the present disclosure.

FIG. 15E is a graph showing changes in absorption rate for each wavelength band of a first sub-metal layer having a relatively high deposition rate of 3.5 Å/s and a second sub-metal layer having a relatively low deposition rate of 1.75 Å/s according to one or more embodiments of the present disclosure.

### DETAILED DESCRIPTION

Advantages and features of the present disclosure and implementation methods thereof will be clarified through following embodiments described with reference to the accompanying drawings. The present disclosure may, however, be embodied in different forms and should not be construed as limited to the embodiments set forth herein. Rather, these embodiments are provided so that this disclosure will be thorough and complete and will fully convey the scope of the present disclosure to those skilled in the art. Further, the present disclosure is only defined by scopes of claims.

A shape, a size, a ratio, an angle and a number disclosed in the drawings for describing embodiments of the present disclosure are merely an example and thus, the present disclosure is not limited to the illustrated details. Like reference numerals refer to like elements throughout the specification. In the following description, when the detailed description of the relevant known function or configuration is determined to unnecessarily obscure the important point of the present disclosure, the detailed description will be omitted. In a case where ‘comprise’, ‘have’ and ‘include’ described in the present disclosure are used, another portion may be added unless ‘only’ is used. The terms of a singular form may include plural forms unless referred to the contrary.

In construing an element, the element is construed as including an error band although there is no explicit description.

In describing a position relationship, for example, when the position relationship is described as ‘upon’, ‘above’, ‘below’ and ‘next to’, one or more portions may be disposed between two other portions unless ‘just’ or ‘direct’ is used.

In the case of a description of a temporal relationship, for example, if the temporal precedence relationship is described as ‘after’, ‘subsequently’, ‘next to’, and ‘before’, or if it is not continuous unless ‘right’ or ‘direct’ is used.

It will be understood that, although the terms “first,” “second,” etc. may be used herein to describe various elements, these elements should not be limited by these terms. These terms are only used to distinguish one element from another. For example, a first element could be termed a second element, and, similarly, a second element could be termed a first element, without departing from the scope of the present disclosure.

Features of various embodiments of the present disclosure may be partially or overall coupled to or combined with each other and may be variously inter-operated with each other and driven technically as those skilled in the art can sufficiently understand. The embodiments of the present disclosure may be carried out independently from each other or may be carried out together in a co-dependent relationship.

Hereinafter, the preferred embodiments of the present disclosure will be described in detail with reference to the accompanying drawings.

FIG. 1 is a schematic plan view of an electroluminescent display device according to one or more embodiments of the present disclosure.

As shown in FIG. 1, the electroluminescent display device according to one or more embodiments of the present disclosure includes a plurality of sub-pixels (1st sub-pixel, 2nd sub-pixel, 3rd sub-pixel, and 4th sub-pixel).

The plurality of sub-pixels (1st sub-pixel, 2nd sub-pixel, 3rd sub-pixel, 4th sub-pixel) includes a plurality of light emitting areas (EA1, EA2, EA3, EA4).

Specifically, the first sub-pixel (1st sub-pixel) includes the first light emitting area (EA1), the second sub-pixel (2nd sub-pixel) includes the second light emitting area (EA2), the third sub-pixel (3rd sub-pixel) includes the third light emitting area (EA3), and the fourth sub-pixel (4th sub-pixel) includes the fourth light emitting area (EA4).

A bank 400 is disposed between the light emitting areas (EA1, EA2, EA3, EA4). The bank 400 may have a matrix structure extending in horizontal and vertical directions. The light emitting areas (EA1, EA2, EA3, EA4) are defined by the bank 400.

The first light emitting area (EA1) may emit cyan (C) light, the second light emitting area (EA2) may emit blue (B) light, the third light emitting area (EA3) may emit green (G) light, and the fourth light emitting area (EA4) may emit red (R) light.

FIG. 1 shows that the fourth light emitting area (EA4), the third light emitting area (EA3), the first light emitting area (EA1), and the second light emitting area (EA2) are arranged in order from left to right, but the present disclosure is not limited thereto.

The first sub-pixel (1st sub-pixel) may be disposed between the second sub-pixel (2nd sub-pixel) and the third sub-pixel (3rd sub-pixel). That is, the second sub-pixel (2nd sub-pixel) may be disposed at one side of the first sub-pixel (1st sub-pixel), for example, on a right side of the first sub-pixel (1st sub-pixel), and the third sub-pixel (3rd sub-pixel) may be disposed at the other side of the first sub-pixel (1st sub-pixel), for example, on the left side of the first sub-pixel (1st sub-pixel). Accordingly, the first light emitting area (EA1) emitting the cyan (C) light may be disposed between the second light emitting area (EA2) emitting the blue (B) light and the third light emitting area (EA3) emitting the green (G) light.

As will be described later, the first light emitting area (EA1) emitting the cyan (C) light includes a first sub-light emitting area emitting green light and a second sub-light emitting area emitting blue light. Accordingly, when the first light emitting area (EA1) is located between the second light emitting area (EA2) and the third light emitting area (EA3), even if a leakage current is generated between adjacent sub-pixels (1st sub-pixel, 2nd sub-pixel, 3rd sub-pixel), a problem of color mixing may be minimized. However, the present disclosure is not limited thereto, and the first sub-pixel (1st sub-pixel) may be disposed between the third sub-pixel (3rd sub-pixel) and the fourth sub-pixel (4th sub-pixel), or may be disposed between the second sub-pixel (2nd sub-pixel) and the fourth sub-pixel (4th sub-pixel).

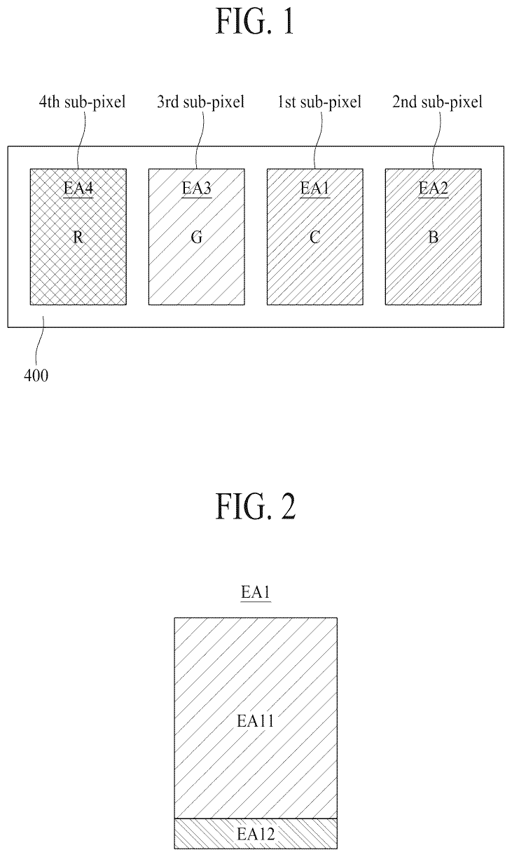

FIGS. 2 to 5 are schematic plan views of a first light emitting area emitting cyan-colored light according to one or more embodiments of the present disclosure.

As shown in FIGS. 2 to 5, the first light emitting area (EA1) includes a first sub-light emitting area (EA11) and a second sub-light emitting area (EA12).

The first sub-light emitting area (EA11) is an area emitting green light, and the second sub-light emitting area (EA12) is an area emitting blue light. The first sub-light emitting area (EA11) and the second sub-light emitting area (EA12) are in contact with each other.

The first sub-light emitting area (EA11) and the second sub-light emitting area (EA12) may be variously disposed.

According to an embodiment, as shown in FIG. 2, the second sub-light emitting area (EA12) may be disposed at on one side of the first sub-light emitting area (EA11), for example, below the first sub-light emitting area (EA11). For example, when the first light emitting area (EA1) has a rectangular structure having a vertical direction longer than a horizontal direction, the second sub-light emitting area (EA12) has a bar structure extending in the horizontal direction, and the first sub-light emitting area (EA11) may be disposed on an upper side of the second sub-light emitting area (EA12) while contacting an upper surface of the second sub-light emitting area (EA12).

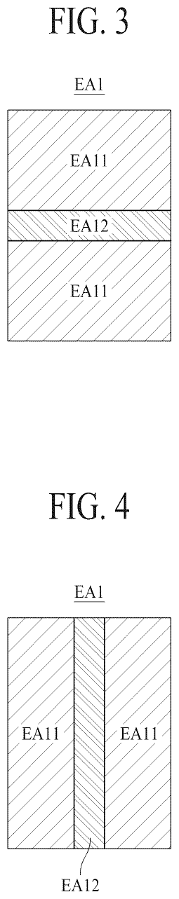

According to another embodiment, as shown in FIG. 3, the two sub-light emitting area (EA11) may be disposed to be vertically spaced apart from each other with the second sub-light emitting area (EA12) therebetween. As an example, when the first light emitting area (EA1) has the rectangular structure having the vertical direction longer than the horizontal direction, the second sub-light emitting area (EA12) has a bar structure extending in the horizontal direction, and the two first sub-light emitting area (EA11) may be disposed on an upper side and a lower side of the second sub-light emitting area (EA12) while contacting an upper surface and a lower surface of the second sub-light emitting area (EA12).

According to another embodiment, as shown in FIG. 4, the two sub-light emitting area (EA11) may be disposed to be spaced apart from each other in left and right directions with the second sub-light emitting area (EA12) therebetween. As an example, when the first light emitting area (EA1) has the rectangular structure having the vertical direction longer than the horizontal direction, the second sub-light emitting area (EA12) has a bar structure extending in the vertical direction, and the two first sub-light emitting area (EA11) may be disposed on an left side and a light side of the second sub-light emitting area (EA12) while contacting an left surface and a right surface of the second sub-light emitting area (EA12).

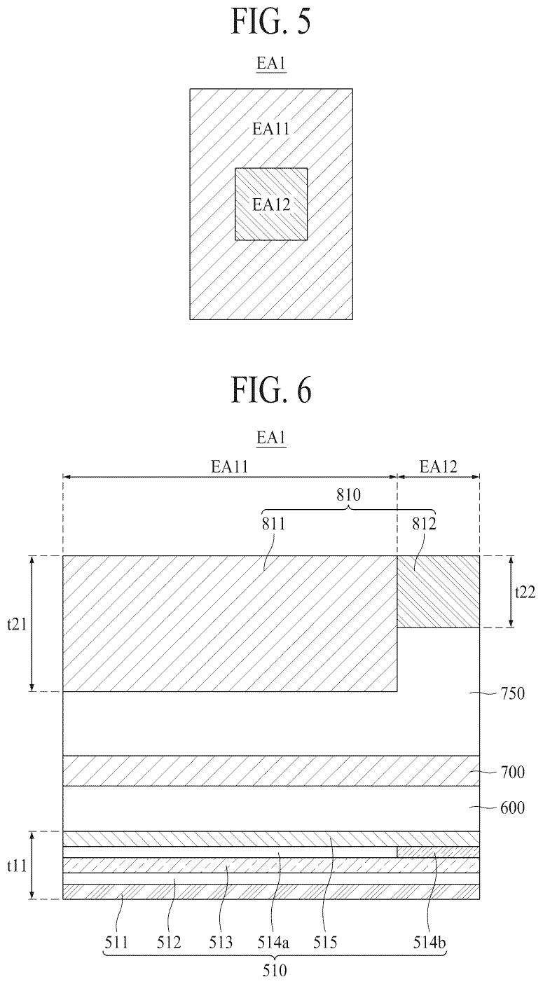

According to another embodiment, as shown in FIG. 5, the first sub-light emitting area (EA11) may be disposed to entirely surround the second sub-light emitting area (EA12). As an example, when the first light emitting area (EA1) has the rectangular structure having the vertical direction longer than the horizontal direction, the second sub-light emitting area (EA12) has a rectangular or square structure in a center of the first light emitting area (EA1). Also, the first sub-light emitting area (EA11) may have a rectangular structure surrounding the second sub-light emitting area (EA12) while contacting an entire outer periphery of the second sub-light emitting area (EA12).

In FIGS. 2 to 5, it may be preferable that an area of the first sub-light emitting area (EA11) is larger than an area of the second sub-light emitting area (EA12).

Specifically, it may be preferable in terms of color reproducibility that a ratio of an area of the first sub-light emitting area (EA11) to an area of the second sub-light emitting area (EA12) is in a range of 7:3 to 9:1, which will be described later.

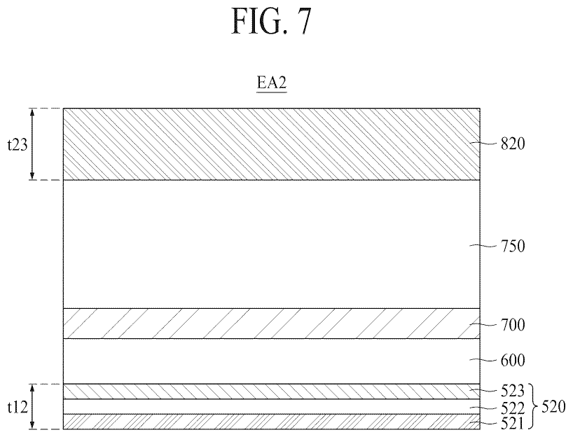

FIG. 6 is a partial cross-sectional view of a first light emitting area (EA1) emitting cyan (C) light according to one or more embodiments of the present disclosure, and FIG. 7 is a partial cross-sectional view of a second light emitting area (EA2) emitting blue light according to one or more embodiments of the present disclosure.

As shown in FIG. 6, the first light emitting area (EA1) includes a first electrode 510, a light emitting layer 600, a second electrode 700, an encapsulation layer 750, and a first color filter 810.

The first electrode 510 may function as an anode.

The first electrode 510 may have a first thickness (t11), may include a plurality of layers and may have low reflection characteristics. For example, the first electrode 510 may include a first transparent conductive layer 511, a first metal layer 512, a second transparent conductive layer 513, a second metal layer 514a, 514b, and a third transparent conductive layer 515.

The first transparent conductive layer 511 may be formed of ITO, but is not necessarily limited thereto. The first metal layer 512 is disposed on the first transparent conductive layer 511 and may be formed of Ag, but is not necessarily limited thereto. The second transparent conductive layer 513 is disposed on the first metal layer 512 and may be formed of a material different from the first transparent conductive layer 511, for example, IZO, but is not necessarily limited thereto. The second metal layer 514a and 514b are disposed on the second transparent conductive layer 513 and may be formed of a material different from the first metal layer 512, for example, Al, but is not necessarily limited thereto. The third transparent conductive layer 515 is disposed on the second metal layers 514a and 514b, and may be formed of the same material as the first transparent conductive layer 511 and, for example, ITO, but is not limited thereto.

A thickness of the second transparent conductive layer 513 may be thicker than a thickness of the first transparent conductive layer 511 and a thickness of the third transparent conductive layer 515, and the thickness of the first transparent conductive layer 511 may be the same as the thickness of the third transparent conductive layer 515. Also, A thickness of the second metal layer 514a, 514b may be thinner than a thickness of the first metal layer 512 and a thickness of the first transparent conductive layer 511, and the thickness of the first metal layer 512 may be thicker than the thickness of the second transparent conductive layer 513, but is not limited thereto.

The first transparent conductive layer 511, the first metal layer 512, the second transparent conductive layer 513, and the third transparent conductive layer 515 are disposed to be continuous in the first sub-light emitting area (EA11) and the second sub-light emitting area (EA12) while overlapping the entire first sub-light emitting area (EA11) and the entire second sub-light emitting area (EA12).

The second metal layers 514a, 514b include a first sub-metal layer 514a and a second sub-metal layer 514b. The first sub-metal layer 514a overlaps the first sub-light emitting area (EA11), and the second sub-metal layer 514b overlaps the second sub-light emitting area (EA12). Therefore, an area of the first sub-metal layer 514a is larger than an area of the second sub-metal layer 514b.

The first sub-metal layer 514a and the second sub-metal layer 514b may be in contact with each other at a boundary between the first sub-light emitting area (EA11) and the second sub-light emitting area (EA12).

The first sub-metal layer 514a and the second sub-metal layer 514b may be formed of the same metal, for example, Al. Also, the first sub-metal layer 514a and the second sub-metal layer 514b may be formed by the same deposition process, for example, a sputtering process.

However, it may be preferable in terms of color reproducibility that a deposition rate of the first sub-metal layer 514a is higher than a deposition rate of the second sub-metal layer 514b. For example, when the deposition rate of the first sub-metal layer 514a is in the range of 3.0 Å/s to 3.7 Å/s, a FWHM (Full Width at Half Maximum) of green light in the first sub-light emitting area (EA11) is reduced, and thus color reproducibility may be improved. Also, when the deposition rate of the second sub-metal layer 514b is in the range of 1.7 Å/s to 2.0 Å/s, a FWHM (Full Width at Half Maximum) of blue light in the second sub-light emitting area (EA12) is reduced, and thus color reproducibility may be improved. The deposition rate of the first sub-metal layer 514a and the deposition rate of the second sub-metal layer 514b will be described in detail later.

The first electrode 510 includes the second metal layers 514a, 514b and has low reflection characteristics, and is not necessarily required to have a five-layer structure.

The light emitting layer 600 is disposed on the first electrode 510. The light emitting layer 600 may be emit white light. The light emitting layer 600 may include a first stack emitting light of a first color, a second stack emitting light of a second color, and a charge generation layer disposed between the first stack and the second stack. The first color may be one of blue and yellow-green, and the second color may be the other of blue and yellow-green.

The second electrode 700 is disposed on the light emitting layer 600. The second electrode 700 may function as a cathode. The second electrode 700 may include a transparent electrode or a translucent electrode.

The encapsulation layer 750 is disposed on the second electrode 700. The encapsulation layer 750 may include an inorganic insulating layer and an organic insulating layer.

The first color filter 810 is disposed on the encapsulation layer 750. The first color filter 810 transmits cyan light.

The first color filter 810 includes a first sub-color filter 811 and a second sub-color filter 812. The first sub-color filter 811 overlaps the first sub-light emitting area (EA11), and the second sub-color filter 812 overlaps the second sub-light emitting area (EA12). The first color filter 811 and the second sub-color filter 811 may be in contact with each other at a boundary between the first sub-light emitting area (EA11) and the second sub-light emitting area (EA12).

The first sub-color filter 811 may be formed of a green color filter that transmits green light, and the second sub-color filter 812 may be formed of a blue color filter that transmits blue light.

When an area of the first sub-color filter 811 is larger than an area of the second sub-color filter 812, it may be advantageous in terms of color reproducibility.

It may be advantageous in terms of color reproducibility that a first thickness t21 of the first sub-color filter 811 is thicker than a second thickness t22 of the second sub-color filter 812. For example, it may be preferable in terms of color reproduction and economic feasibility that a ratio of the first thickness t21 of the first sub-color filter 811 to the second thickness t22 of the second sub-color filter 812 may be in the range of 1.8:1 to 2:1, which is to be described later.

An upper surface of the first sub-color filter 811 and an upper surface of the second sub-color filter 812 may be formed at the same height. Accordingly, a lower surface of the first sub-color filter 811 may be located closer to a second electrode 700 than a lower surface of the second sub-color filter 812.

As shown in FIG. 7, the second light emitting area (EA2) includes a first electrode 520, a light emitting layer 600, a second electrode 700, an encapsulation layer 750, and a second color filter 820.

The first electrode 520 may function as an anode.

The first electrode 520 may have a second thickness t12 and may include a plurality of layers.

The second thickness t12 of the first electrode 520 of the second light emitting area (EA2) may be thinner than the first thickness t11 of the first electrode 510 of the first light emitting area (EA1) described above.

The first electrode 520 of the second light emitting area (EA2) may include a first transparent conductive layer 521, a first metal layer 522, and a second transparent conductive layer 523.

The first transparent conductive layer 521 may be made of ITO, but is not necessarily limited thereto. The first metal layer 522 is disposed on the first transparent conductive layer 521 and may be made of Ag, but is not necessarily limited thereto. The second transparent conductive layer 523 is disposed on the first metal layer 522 and may be made of the same material as the first transparent conductive layer 521, for example, ITO, but is not limited thereto.

A thickness of the first transparent conductive layer 521 may be equal to a thickness of the second transparent conductive layer 523, and a thickness of the first metal layer 522 may be thicker than the thickness of the first transparent conductive layer 521, but is not limited thereto.

The first transparent conductive layer 521 of the second light emitting area (EA2) may be formed of the same material and the same thickness as the first transparent conductive layer 511 of the first light emitting area (EA1).

The first metal layer 522 of the second light emitting area (EA2) may be formed of the same material and the same thickness as the first metal layer 512 of the first light emitting area (EA1).

The second transparent conductive layer 523 of the second light emitting area (EA2) may be formed of the same material and the same thickness as the third transparent conductive layer 515 of the first light emitting area (EA1).

Accordingly, the second transparent conductive layer 513 and the second metal layers 514a and 514b of the first light emitting area (EA1) may not be disposed in the second light emitting area (EA2).

The light emitting layer 600 of the second light emitting area (EA2) may be formed of the same material as the light emitting layer 600 of the first light emitting area (EA1), the second electrode 700 of the second light emitting area (EA2) may be formed of the same material as the second electrode 700 of the first light emitting area (EA1), and the encapsulation layer 750 of the second light emitting area (EA2) may be formed of the same material as the encapsulation layer 750 of the first light emitting area (EA1).

The second color filter 820 of the second light emitting area (EA2) may be formed of a blue color filter that transmits blue light.

A third thickness t23 of the second color filter 820 of the second light emitting area (EA2) may be thinner than the first thickness t21 of the first sub color filter 811 of the first light emitting area (EA1) and may be the same as the second thickness t22 of the second sub color filter 812 of the first light emitting area (EA1). Alternatively, the third thickness t23 of the second color filter 820 of the second light emitting area (EA2) may be thinner than the second thickness t22 of the second sub color filter 812 of the first light emitting area (EA1).

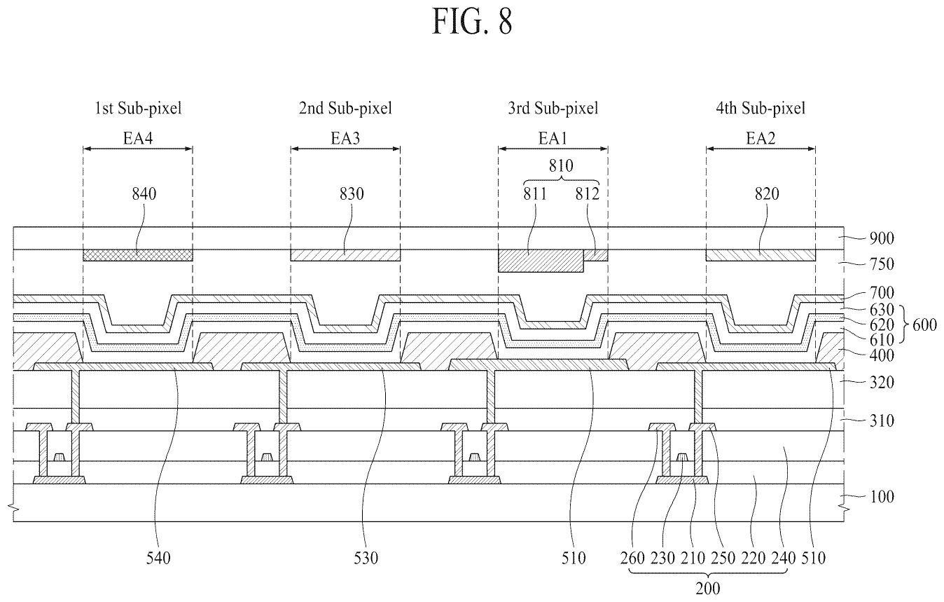

FIG. 8 is a schematic cross-sectional view of an electroluminescent display device according to one or more embodiments of the present disclosure.

As shown in FIG. 8, the electroluminescent display device according to an embodiment of the present disclosure includes a first substrate 100, a circuit element layer 200, a passivation layer 310, a passivation layer 310, a planarization layer 320, a bank 400, a first electrode 510, 520, 530, 540, a light emitting layer 600, a second electrode 700, an encapsulation layer 750, a color filter 810, 820, 830, 840, and a second substrate 900.

The first substrate 100 may be made of glass, plastic, or a semiconductor material, but is not necessarily limited thereto. The electroluminescent display device according to an embodiment of the present disclosure may be a top emission type, and accordingly, not only a transparent material but also an opaque material may be used as a material of the first substrate 100.

The circuit element layer 200 is disposed on the first substrate 100.

The circuit element layer 200 includes a driving thin film transistor disposed for each of the first to fourth sub-pixels (1st sub-pixel, 2nd sub-pixel, 3rd sub-pixel, 4th sub-pixel).

The driving thin film transistor includes an active layer 210 disposed on the first substrate 100, a gate insulating layer 220 disposed on the active layer 210, a gate electrode 230 disposed on the gate insulating layer 220, an interlayer insulating layer 240 disposed on the gate electrode 230, and a source electrode 250 and a drain electrode 260 disposed on the interlayer insulating layer 240. The source electrode 250 and the drain electrode 260 are connected with one side and the other side of the active layer 210 through holes disposed in the interlayer insulating layer 240 and the gate insulating layer 220.

Although the driving thin film transistor having a top gate structure in which the gate electrode 230 is disposed on the active layer 210 is illustrated in the drawing, the present disclosure may include a driving thin film transistor having a bottom gate structure in which the gate electrode 230 is disposed under the active layer 210. Also, although the gate insulating layer 220 is formed on an entire surface of the first substrate 100 in the drawing, the gate insulating layer 220 may be patterned in the same shape as the gate electrode 230 below the gate electrode 230. The driving thin film transistor may be changed in various forms known in the art.

In addition, although not shown, the circuit element layer 200 may further include various signal lines including a gate line, a data line, a power line, and a reference line, various thin film transistors including a switching thin film transistor and a sensing thin film transistor, and a capacitor.

The switching thin film transistor is switched according to a gate signal supplied to the gate line to supply a data voltage supplied from the data line to the driving thin film transistor.

The driving thin film transistor is switched according to the data voltage supplied from the switching thin film transistor. And, the driving thin film transistor generates a data current from a power source supplied from a power line and supplies the data current to the first electrode 510, 520, 530, 540.

The sensing thin film transistor senses a threshold voltage deviation of the driving thin film transistor that causes image quality deterioration. In addition, the sensing thin film transistor supplies a current of the driving thin film transistor to a reference line in response to a sensing control signal supplied from the gate line or a separate sensing line.

The capacitor maintains the data voltage supplied to the driving thin film transistor for one frame, and is connected with a gate terminal and a source terminal of the driving thin film transistor, respectively.

The passivation layer 310 is disposed on the circuit element layer 200. Specifically, the passivation layer 310 is disposed on the source electrode 250 and the drain electrode 260.

The planarization layer 320 is disposed on the passivation layer 310.

The passivation layer 310 and the planarization layer 320 may include a contact hole, and the source electrode 250 may be exposed by the contact hole, and the first electrode 510, 520, 530, 540 may be connected with exposed source electrode 250 through the contact hole. In some cases, the drain electrode 260 may be exposed by a contact hole disposed in the passivation layer 310 and the planarization layer 320, and the first electrode 510, 520, 530, 540 may be connected with exposed drain electrode 260 through the contact hole.

The bank 400 is disposed on the planarization layer 320, and is formed at a boundary between the first to fourth sub-pixels (1st sub-pixel, 2nd sub-pixel, 3rd sub-pixel, and 4th sub-pixel). The bank 400 is disposed on the first electrodes 510, 520, 530, 540 to cover edges of the first electrodes 510, 520, 530, 540 and light emitting areas (EA1, EA2, EA3, EA4) may be defined by the bank 400. That is, portions of the first electrodes 510, 520, 530, 540 exposed by the bank 400 may become light emitting areas (EA1, EA2, EA3, EA4). Accordingly, the first light emitting area (EA1) is disposed in the first sub-pixel (1st sub-pixel), the second light emitting area (EA2) is disposed in the second sub-pixel (2nd sub-pixel), the third light emitting area (EA3) is disposed in the third sub-pixel (3rd sub-pixel), and the fourth light emitting area (EA4) is disposed in the fourth sub-pixel (4th sub-pixel).

The first electrodes 510, 520, 530, and 540 are disposed for each of the first to fourth sub-pixels (1st sub-pixel, 2nd sub-pixel, 3rd sub-pixel, 4th sub-pixel) on the planarization layer 320.

The first electrodes 510, 520, 530, 540 are connected with the source electrode 250 or the drain electrode 260 through contact holes disposed in the passivation layer 310 and the planarization layer 320.

A thickness of the first electrode 510 of the first sub-pixel (1st sub-pixel) is thicker than a thickness of the first electrodes 520, 530, and 540 of the second to fourth sub-pixels (2nd sub-pixel, 3rd sub-pixel, 4th sub-pixel), and the first electrodes 520, 530, and 540 of the second to fourth sub-pixels (2nd sub-pixel, 3rd sub-pixel, 4th sub-pixel) may have the same thickness.

A reflectance of the first electrode 510 of the first sub-pixel (1st sub-pixel) may be lower than a reflectance of the first electrodes 520, 530, and 540 of the second to fourth sub-pixels (2nd sub-pixel, 3rd sub-pixel, 4th sub-pixel).

The first electrode 510 of the first sub-pixel (1st sub-pixel) may include a first transparent conductive layer 511, a first metal layer 512, a second transparent conductive layer 513, second metal layer 514a, 514b, and a third transparent conductive layer 515 as illustrated in FIG. 6.

The first electrodes 520, 530, 540 of the second to fourth sub-pixels (2nd sub-pixel, 3rd sub-pixel, 4th sub-pixel) have the same structure, and may include a first transparent conductive layer 521, a first metal layer 522, and a second transparent conductive layer 523 as illustrated in FIG. 7.

The light emitting layer 600 is disposed on the first electrodes 510, 520, 530, 540 and the bank 400. The light emitting layer 600 may emit white light, but is not limited thereto. The light emitting layer 600 may be disposed in each of sub-pixels (1st sub-pixel, 2nd sub-pixel, 3rd sub-pixel, 4th sub-pixel), and a boundary area therebetween. The light emitting layer 600 may be continuous between all of the sub-pixels (1st sub-pixel, 2nd sub-pixel, 3rd sub-pixel, 4th sub-pixel) without being disconnected.

The light emitting layer 600 may include a first stack 610, a charge generation layer 620, and a second stack 630. The first stack 610 may be disposed on the first electrodes 510, 520, 530, 540 and the bank 400, the charge generation layer 620 may be disposed on the first stack 610, and the second stack 630 may be disposed on the charge generation layer 620.

The first stack 610 may emit one light of blue and yellow-green, and the second stack 630 may emit the other light of blue and yellow-green. For example, the first stack 610 may emit blue light, and the second stack 630 may emit yellow-green light. In some cases, the second stack 630 may emit a mixed light of yellow-green light and red light.

Each of the first stack 610 and the second stack 630 may include at least one of a hole injection layer, a hole transport layer, an electron blocking layer, an organic emission layer, a hole blocking layer, an electron transport layer, and an electron injection layer.

The charge generation layer 620 may include an N-type charge generation layer disposed on the first stack 610 to supply electrons to the first stack 610, and a P-type charge generation layer disposed on the N-type charge generation layer to supply holes to the second stack 630.

As shown, the light emitting layer 600 is not limited to a two stack structure, and may be have a stack structure including three or more stacks and two or more charge generation layers.

The encapsulation layer 750 is disposed on the light emitting layer 600.

The encapsulation layer 750 may have a three-layer structure of a first inorganic insulating layer, an organic insulating layer disposed on the first inorganic insulating layer, and a second inorganic insulating layer disposed on the organic insulating layer, but is not limited thereto. The encapsulation layer 750 may be continuous between all sub-pixels (1st sub-pixel, 2nd sub-pixel, 3rd sub-pixel, 4th sub-pixel) without being disconnected.

The color filters 810, 820, 830, and 840 are disposed for each sub-pixel (1st sub-pixel, 2nd sub-pixel, 3rd sub-pixel, and 4th sub-pixel) on the encapsulation layer 750.

The first color filter 810 overlaps the first light emitting area (EA1) in the first sub-pixel (1st sub-pixel), the second color filter 820 overlaps the second light emitting area (EA2) in the second sub-pixel (2nd sub-pixel), the third color filter 830 overlaps the third light emitting area (EA3) in the third sub-pixel (3rd sub-pixel), and the fourth color filter 840 overlaps the fourth light emitting area (EA4) in the fourth sub-pixel (4th sub-pixel).

The first color filter 810 may transmit cyan light, and includes a first sub-color filter 811 transmitting a green light and a second sub-color filter 812 transmitting a blue light as shown in FIG. 6 described above.

The second color filter 820 may be formed of a blue color filter that transmits blue light as shown in FIG. 7 described above.

The third color filter 830 may be formed of a green color filter that transmits green light, and the fourth color filter 840 may be formed of a red color filter that transmits red light. A thickness of the third color filter 830 and a thickness of the fourth color filter 840 may be the same as the thickness of the second color filter 820.

A height of an upper surfaces of each of the color filters 810, 820, 830, 840 may be the same as each other.

The second substrate 900 is disposed on the color filters 810, 820, 830, 840. The second substrate 900 is made of a transparent material. After the color filters 810, 820, 830, 840 are formed on the second substrate 900, the color filters 810, 820, 830, 840 may be adhered while facing the encapsulation layer 750.

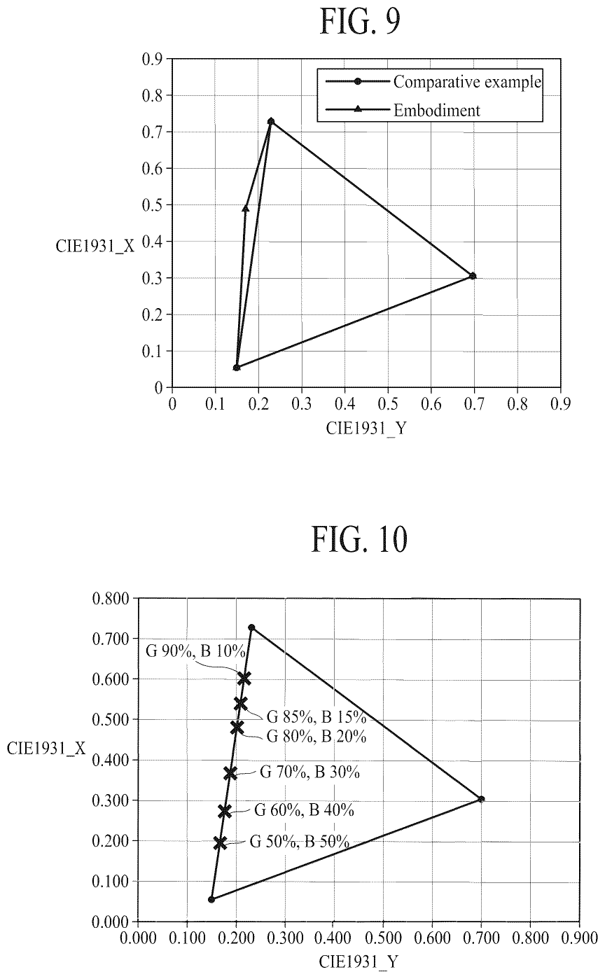

FIG. 9 is a graph showing color reproducibility according to one or more embodiments of the present disclosure, and Table 1 below shows efficiency, color coordinate, color reproducibility, and optical characteristics for each sub-pixel according to one or more embodiments of the present disclosure.

In FIG. 9 and Table 1, a comparative example relates to an electroluminescent display device not provided with a first sub-pixel emitting a cyan light in the structure of FIG. 8, and an embodiment is a case in which the first electrode 510 and the first color filter 810 of FIG. 6 are applied to the structure of FIG. 8, and the ratio of the area of the first sub-light emitting area EA11 to the area of the second sub-light emitting area EA12 is 8.5:1.5, and the ratio of the first thickness t21 of the first sub-color filter 811 to the second thickness t22 of the second sub-color filter 812 is 2:1.

In FIG. 9 and Table 1, a comparative example relates to an electroluminescent display device not including a first sub-pixel emitting a cyan light in the structure of FIG. 8 described above, and an embodiment relates to a case in which the first electrode 510 and the first color filter 810 of FIG. 6 are applied to the structure of FIG. 8. Specifically, in an embodiment, a ratio of an area of the first sub-light emitting area (EA11) to an area of the second sub-light emitting area (EA12) is 8.5:1.5, and a ratio of the first thickness t21 of the first sub-color filter 811 to the second thickness t22 of the second sub-color filter 812 is 2:1.

As shown in Table 1 below, it may be seen that the embodiment has improved efficiency (Cd/A) for each sub-pixel compared to the comparative example.

In addition, as can be seen from Table 1 and FIG. 9, in the case of the embodiment, as the cyan color is added, the color reproducibility may be about 3% better than the comparative example that the cyan color is not added.

In addition, as Table 1 shows, the embodiment reduces a cell reflectance by 2.6% compared to the comparative example, and accordingly, a transmittance of a transmission controllable film (OTF) for preventing reflection can be improved, thereby improving luminance.

TABLE 1

| | | comparative | |
|---|---|---|---|
| | | example | embodiment |
| efficiency | R | 9.2 | 13.3 |
| [Cd/A] | G | 21.5 | 31.3 |
| | B | 2.5 | 3.7 |
| | C | — | 11.1 |
| color coordinate | Rx | 0.698 | 0.698 |
| | Ry | 0.304 | 0.304 |
| | Gx | 0.231 | 0.231 |
| | Gy | 0.727 | 0.727 |
| | Bx | 0.150 | 0.150 |
| | By | 0.053 | 0.053 |
| | Cx | — | 0.172 |
| | Cy | — | 0.490 |
| color | BT.2020 | 85.3% | 88.39% |
| reproducibility | | | |
| optical | Cell reflectance | 9.0% | 6.4% |
| characteristics | OTF | 54% | 79% |
| | transmittance | | |
| | luminance | 100% | 145% |

FIG. 10 is a graph showing a change in color reproducibility by changing a ratio of an area of the first sub-light emitting area (EA11) to an area of the second sub-light emitting area (EA12) while maintaining a ratio of a first thickness t21 of the first sub-color filter 811 to a second thickness t22 of the second sub-color filter 812 as 1:1 in the structure of FIG. 8 described above according to one or more embodiments of the present disclosure, and Table 2 below shows the results.

As shown in FIG. 10 and Table 2, it may be seen that there is no change in color reproducibility even when the ratio of the area of the first sub-light emitting area (EA11) to the area of the second sub-light emitting area (EA12) is changed. Accordingly, when the ratio of the first thickness t21 of the first sub-color filter 811 to the second thickness t22 of the second sub-color filter 812 is set to 1:1, it may be seen that it is difficult to improve the color reproducibility.

TABLE 2

| area of first | area of second | | | color |
|---|---|---|---|---|
| sub-light | sub-light | | | reproducibility |
| emitting area(G) | emitting area(B) | Cx | Cy | BT.2020 |
| 50% | 50% | 0.167 | 0.195 | 85.3% |
| 60% | 40% | 0.176 | 0.273 | 85.3% |
| 70% | 30% | 0.187 | 0.369 | 85.3% |
| 80% | 20% | 0.201 | 0.480 | 85.3% |
| 85% | 15% | 0.208 | 0.540 | 85.3% |
| 90% | 10% | 0.215 | 0.602 | 85.3% |

FIG. 11 is a graph showing a change in color reproducibility by changing a ratio of the area of the first sub-light emitting area (EA11) to the area of the second sub-light emitting area (EA12) while maintaining a ratio of the first thickness t21 of the first sub-color filter 811 to a second thickness t22 of the second sub-color filter 812 as 2:1 in the structure of FIG. 8 described above according to one or more embodiments of the present disclosure, and Table 3 below shows the results.

As shown in FIGS. 11 and Table 3, it may be seen that when the area of the first sub-light emitting area (EA11) is larger than the area of the second sub-light emitting area (EA12), color reproducibility is improved.

In particular, when a ratio of the area of the first sub-light emitting area (EA11) to the area of the second sub-light emitting area (EA12) is in the range of 7:3 to 9:1, the color reproducibility is excellent at 87% or more.

Meanwhile, referring to the color coordinate of FIG. 11, it may be seen that the optimal cyan color may be realized when the ratio of the area of the first sub-light emitting area (EA11) to the area of the second sub-light emitting area (EA12) is 8.5:1.5.

TABLE 3

| area of first | area of second | | | color |
|---|---|---|---|---|
| sub-light | sub-light | | | reproducibility |
| emitting area(G) | emitting area(B) | Cx | Cy | BT.2020 |
| 50% | 50% | 0.157 | 0.156 | 86.3% |
| 60% | 40% | 0.162 | 0.221 | 86.6% |
| 70% | 30% | 0.168 | 0.309 | 87.0% |
| 80% | 20% | 0.177 | 0.426 | 87.3% |
| 85% | 15% | 0.182 | 0.497 | 87.4% |
| 90% | 10% | 0.188 | 0.576 | 87.5% |

Table 4 below shows a change in color reproducibility by changing a ratio of the first thickness t21 of the first sub-color filter 811 to a second thickness t22 of the second sub-color filter 812 while maintaining a ratio of the area of the first sub-light emitting area (EA11) to the area of the second sub-light emitting area (EA12) as 8.5:1.5 in the structure of FIG. 8 described above.

As shown in Table 4, when the first thickness t21 of the green (G) first sub-color filter 811 is thicker than the second thickness t22 of the blue (B) second sub-color filter 812, the color reproducibility is improved compared to the opposite case.

In particular, when the second thickness t22 of the blue (B) second sub-color filter 812 is maintained at 100%, if the first thickness t21 of the green (G) first sub-color filter 811 is in the range of 180% to 200%, the color reproducibility is excellent at 87% or more. In addition, when the first thickness t21 of the green (G) first sub-color filter 811 is maintained at 200%, if the second thickness t22 of the blue (B) second sub-color filter 812 is in the range of 100% to 200%, the color reproducibility is excellent at 87.4% or more. Here, when the thicknesses of the first and second sub-color filters 811 and 812 are 100%, it means that the thicknesses of the first and second sub-color filters 811 and 812 are the same as the thickness of the second color filter 820 of FIG. 8.

Therefore, in order to obtain a value having a color reproducibility of 87% or more, the first thickness t21 of the first sub-color filter 811 may be formed 1.8 to 2.0 times the thickness of the second color filter 820, and the second thickness t22 of the second sub-color filter 812 may be formed 1.0 to 2.0 times the thickness of the second color filter 820.

As described above, when the first thickness t21 of the green (G) first sub-color filter 811 is maintained at 200%, and the second thickness t22 of the blue (B) second sub-color filter 812 is in the range of 100% to 200%, the color reproducibility may be the same. In consideration of this point, it may be preferable to form the second thickness t22 of the second sub-color filter 812 to 100%, that is, to be the same as the thickness of the second color filter 820 in terms of reducing material costs and the like.

TABLE 4

| the first | the second | | | |
|---|---|---|---|---|
| thickness of the | thickness of the | | | color |
| first sub-color | second sub-color | | | reproducibility |
| filter (G) | filter (B) | Cx | Cy | BT.2020 |
| 40% | 100% | 0.242 | 0.494 | 85.3% |
| 60% | 100% | 0.227 | 0.531 | 85.3% |
| 80% | 100% | 0.217 | 0.542 | 85.3% |
| 100% | 100% | 0.208 | 0.540 | 85.3% |
| 120% | 100% | 0.201 | 0.534 | 85.9% |
| 140% | 100% | 0.195 | 0.526 | 86.4% |
| 160% | 100% | 0.190 | 0.517 | 86.8% |
| 180% | 100% | 0.186 | 0.507 | 87.1% |
| 200% | 100% | 0.182 | 0.497 | 87.4% |
| 200% | 120% | 0.182 | 0.504 | 87.4% |
| 200% | 140% | 0.183 | 0.511 | 87.4% |
| 200% | 160% | 0.184 | 0.518 | 87.4% |
| 200% | 180% | 0.184 | 0.526 | 87.4% |
| 200% | 200% | 0.185 | 0.533 | 87.4% |

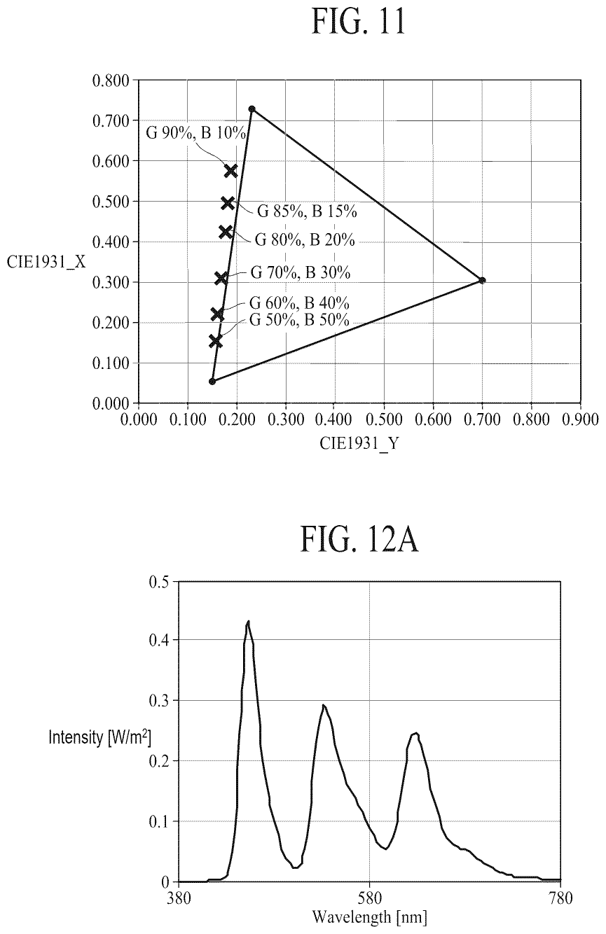

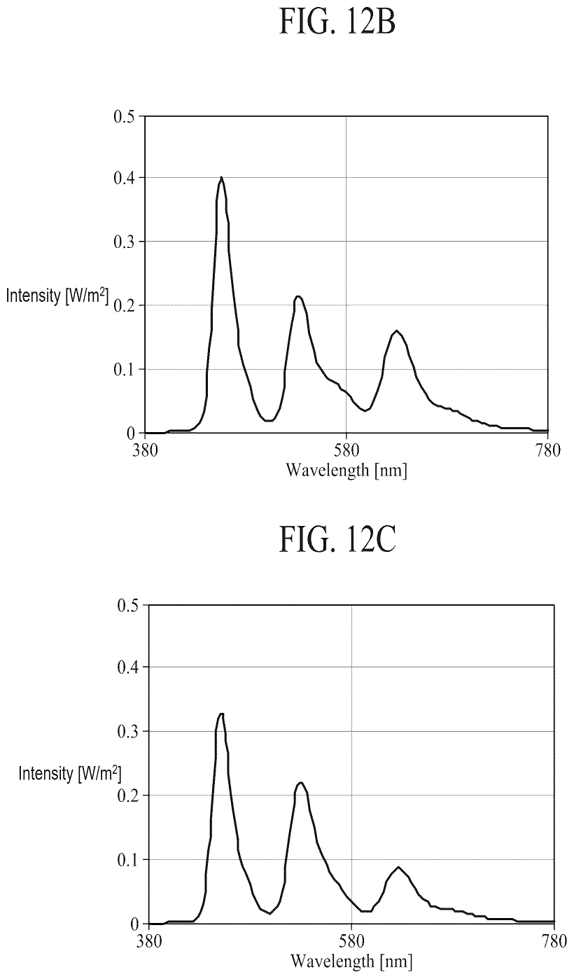

FIG. 12A shows an optical spectrum for each wavelength when the first electrode 520 having a three-layer structure is applied as shown in FIG. 7 according to one or more embodiments of the present disclosure, FIG. 12B shows an optical spectrum for each wavelength when the first electrode 510 with a five-layer structure is applied as shown in FIG. 6 and only the first sub-metal layer 514a with a relatively high deposition rate of 3.5 Å/s is applied as the second metal layers 514a and 514b according to one or more embodiments of the present disclosure, FIG. 12C shows an optical spectrum for each wavelength when the first electrode 510 with a five-layer structure is applied as shown in FIG. 6 and only the second sub-metal layer 514b with a relatively low deposition rate of 1.75 Å/s is applied as the second metal layers 514a and 514b according to one or more embodiments of the present disclosure.

The case of FIGS. 12B and 12C shows that an emission intensity is slightly reduced compared to the case of FIG. 12A because the reflectance of the first electrode 510 applied to FIGS. 12B and 12C is lower than the reflectance of the first electrode 520 applied to FIG. 12A.

On the other hand, in the case of FIGS. 12B and 12C, it can be seen that a full width at half maximum (FWHM) of light has a smaller value compared to that of FIG. 12A. Accordingly, the color reproducibility can be improved in the case of FIGS. 12B and 12C compared to the case of FIG. 12A.

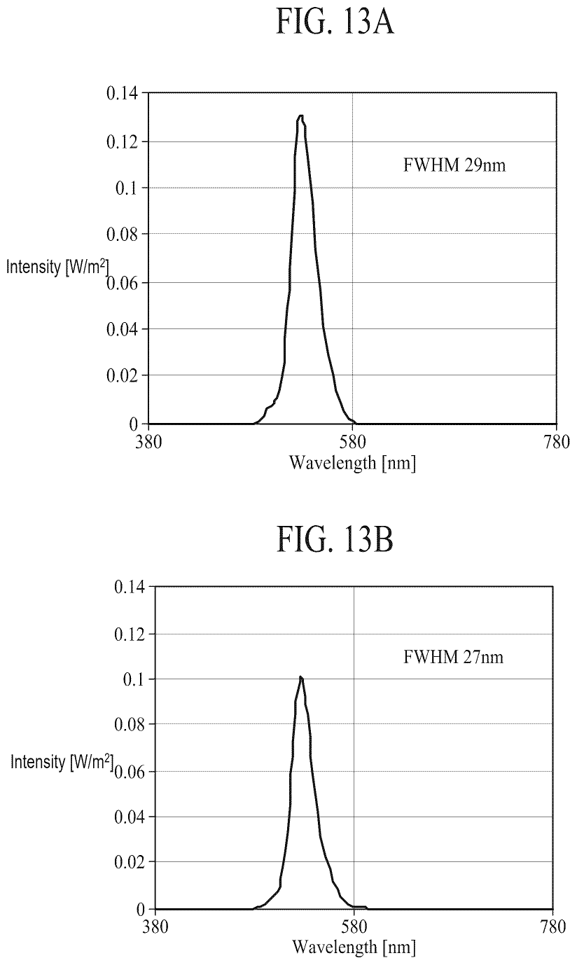

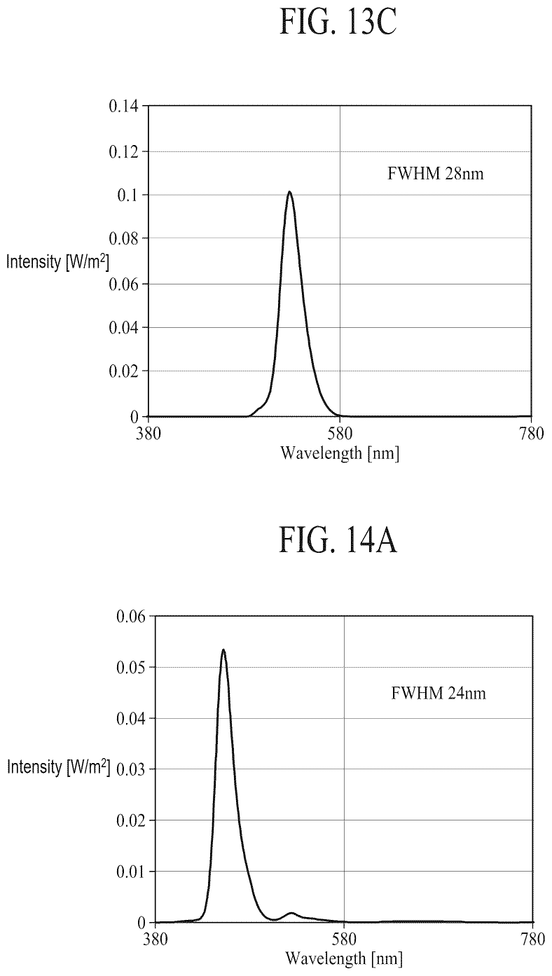

FIG. 13A shows an optical spectrum in which a green color filter is applied to the optical spectrum of FIG. 12A according to one or more embodiments of the present disclosure, FIG. 13B shows an optical spectrum in which a green color filter is applied to the optical spectrum of FIG. 12B according to one or more embodiments of the present disclosure, and FIG. 13C shows an optical spectrum in which a green color filter is applied to the optical spectrum of FIG. 12C according to one or more embodiments of the present disclosure.

In the case of FIG. 13A, the FWHM of light in a green wavelength band is 29 nm, in the case of FIG. 13B, the FWHM of light in the green wavelength band is 27 nm, in the case of FIG. 13C, the FWHM of light in the green wavelength band is 28 nm. Accordingly, since the FWHM of light in the green wavelength band is smaller in the case of FIG. 13B and FIG. 13C compared to the case of FIG. 13A, the color reproducibility may be improved in the case of FIG. 13B and FIG. 13C compared to the case of FIG. 13A. In addition, since the FWHM of light in the green wavelength band is smaller in the case of FIG. 13B compared to the case of FIG. 13C, the color reproducibility may be improved in the case of FIG. 13B compared to the case of FIG. 13C.

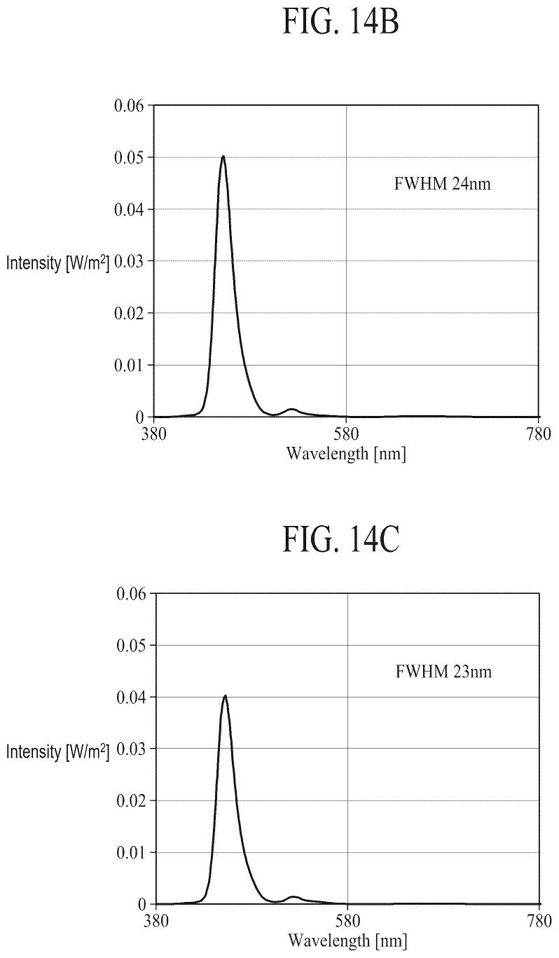

FIG. 14A shows an optical spectrum in which a blue color filter is applied to the optical spectrum of FIG. 12A according to one or more embodiments of the present disclosure, FIG. 14B shows an optical spectrum in which a blue color filter is applied to the optical spectrum of FIG. 12B according to one or more embodiments of the present disclosure, and FIG. 14C shows an optical spectrum in which a blue color filter is applied to the optical spectrum of FIG. 12C according to one or more embodiments of the present disclosure.

In FIG. 14A, the FWHM of light in a blue wavelength band is 24 nm, in FIG. 14B, the FWHM of light in the blue wavelength band is 24 nm, in FIG. 14C, the FWHM of light in the blue wavelength band is 23 nm. Accordingly, it may be seen that the color reproducibility may be improved in the case of FIG. 14C compared to the case of FIG. 14A, since the FWHM of light in the blue wavelength band is smaller in the case of FIG. 14C compared to the case of FIG. 14A. In addition, it may be seen that the color reproducibility may be improved in the case of FIG. 14C compared to the case of FIG. 14B, since the FWHM of light in the blue wavelength band is smaller in the case of FIG. 14C compared to the case of FIG. 14B.

From the above results, it may be seen that color reproducibility may be improved in the case of applying the first electrode 510 having a five-layer structure as illustrated in FIG. 6 compared to the case of applying the first electrode 520 having a three-layer structure as illustrated in FIG. 7.

In addition, from the results of FIGS. 13B and 13C and the results of FIGS. 14B and 14C, it is desirable to correspond the first sub-metal layer 514a having the relatively high deposition rate to the first sub-light emitting area (EA11) and the second sub-metal layer 514b having the relatively low deposition rate to the second sub-light emitting area (EA12).

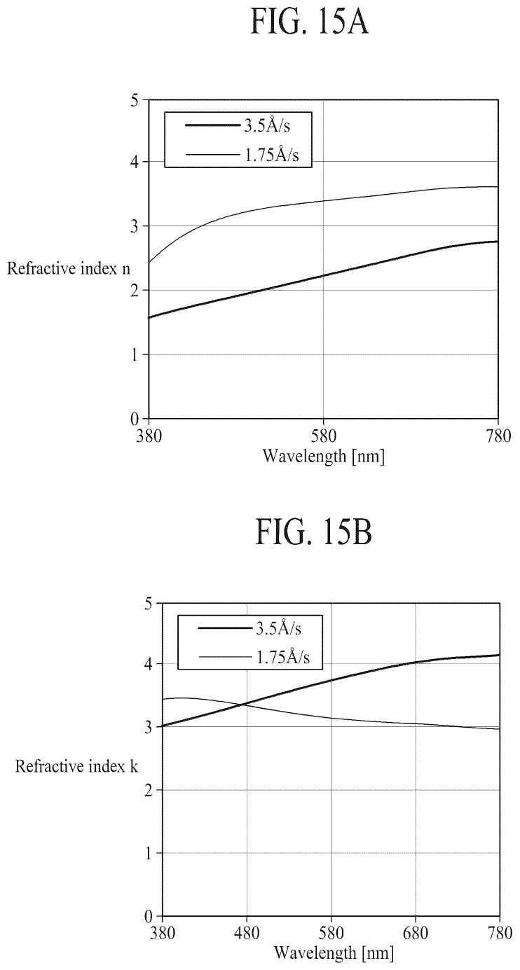

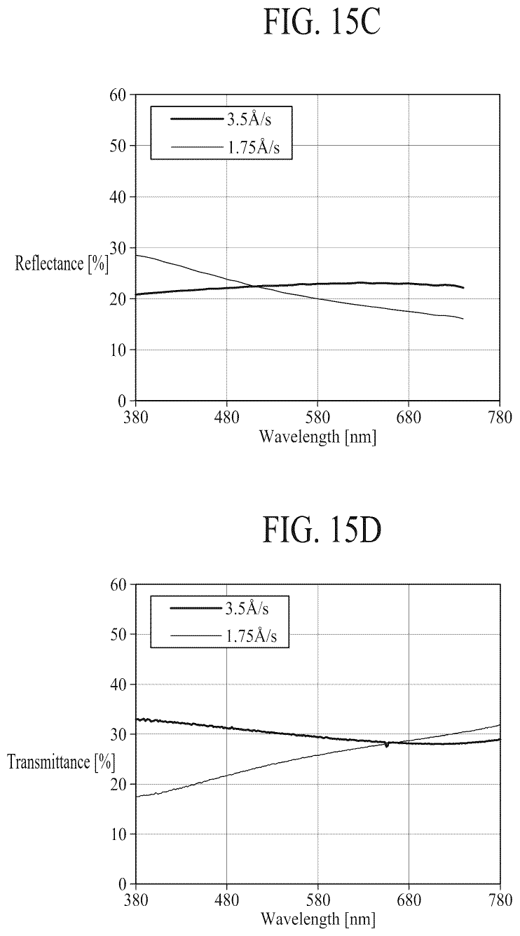

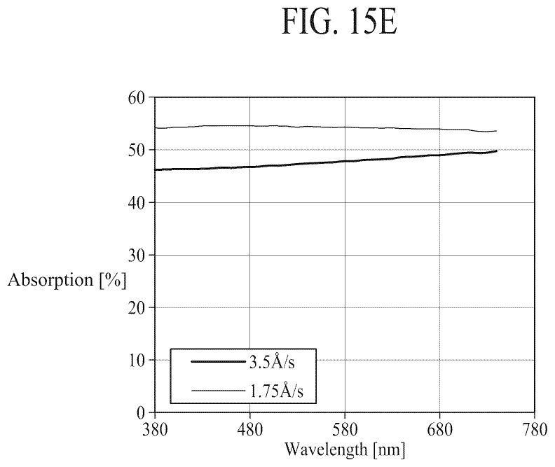

FIGS. 15A to 15E are graphs showing various optical characteristics of the first sub-metal layer 514a having a relatively high deposition rate of 3.5 Å/s and the second sub-metal layer 514b having a relatively low deposition rate of 1.75 Å/s according to one or more embodiments of the present disclosure.

Specifically, FIG. 15A is a graph showing changes in refractive index n for each wavelength band according to one or more embodiments of the present disclosure, FIG. 15B is a graph showing changes in refractive index k for each wavelength band according to one or more embodiments of the present disclosure, FIG. 15C is a graph showing changes in reflectance for each wavelength band according to one or more embodiments of the present disclosure, FIG. 15D is a graph showing changes in transmittance for each wavelength band according to one or more embodiments of the present disclosure and FIG. 15E is a graph showing changes in absorption rate for each wavelength band according to one or more embodiments of the present disclosure. The results according to FIGS. 15A to 15E are shown in Table 5 below.

As shown in FIG. 15A and Table 5, both the refractive index n of the first sub-metal layer 514a of 3.5 Å/s and the refractive index n of the second sub-metal layer 514b of 1.75 Å/s increase from a short wavelength band to a long wavelength band. Furthermore, it may be seen that the refractive index n of the second sub-metal layer 514b of 1.75 Å/s is higher than the refractive index n of the first sub-metal layer 514a of 3.5 Å/s from the short wavelength band to the long wavelength band.

As shown in FIG. 15B and Table 5, it may be seen that the refractive index k of the first sub-metal layer 514a of 3.5 Å/s increases, but the refractive index k of the second sub-metal layer 514b of 1.75 Å/s decreases from a short wavelength band to a long wavelength band.

In addition, in a short wavelength (450 nm), the refractive index k of the second sub-metal layer 514b of 1.75 Å/s is higher than the refractive index k of the first sub-metal layer 514a of 3.5 Å/s, but in a medium wavelength (550 nm) and a long wavelength (650 nm), the refractive index k of the second sub-metal layer 514b of 1.75 Å/s is lower than the refractive index k of the first sub-metal layer 514a of 3.5 Å/s.

As shown in FIG. 15C and Table 5, it may be seen that the reflectance of the first sub-metal layer 514a of 3.5 Å/s increases slightly and then decreases again, but the reflectance of the second sub-metal layer 514b of 1.75 Å/s decreases from the short wavelength band to the long wavelength band.

Furthermore, in the short wavelength (450 nm), the reflectance of the second sub-metal layer 514b of 1.75 Å/s is higher than the reflectance of the first sub-metal layer 514a of 3.5 Å/s, but in the medium wavelength (550 nm) and the long wavelength (650 nm), the reflectance of the second sub-metal layer 514b of 1.75/s is lower than the reflectance of the first sub-metal layer 514a of 3.5 Å/s. On average, the reflectance of the second sub-metal layer 514b of 1.75 Å/s is 20.9%, and the reflectance of the first sub-metal layer 514a of 3.5 Å/s is 22.6%.

As shown in FIG. 15D and Table 5, it may be seen that the transmittance of the first sub-metal layer 514a of 3.5 Å/s decreases slightly and then increases, but the transmittance of the second sub-metal layer 514b of 1.75 Å/s increases from a short wavelength band to a long wavelength band.

Furthermore, in the short wavelength (450 nm) and the medium wavelength (550 nm), the transmittance of the second sub-metal layer 514b of 1.75 Å/s is lower than the transmittance of the first sub-metal layer 514a of 3.5 Å/s, but in the wavelength band of 700 nm or more, the transmittance of the second sub-metal layer 514b of 1.75 Å/s is higher than the transmittance of the first sub-metal layer 514a of 3.5 Å/s. On average, the transmittance of the second sub-metal layer 514b of 1.75 Å/s is 24.7%, and the transmittance of the first sub-metal layer 514a of 3.5 Å/s is 29.9%.

As may be seen from FIGS. 15E and Table 5, it may be seen that the absorption rate of the first sub-metal layer 514a of 3.5 Å/s increases slightly, but the absorption rate of the second sub-metal layer 514b of 1.75 Å/s is almost constant from a short wavelength band to a long wavelength band.

Furthermore, it may be seen that the absorption rate of the second sub-metal layer 514b of 1.75 Å/s is higher than the absorption rate of the first sub-metal layer 514a of 3.5 Å/s from the short wavelength band to the long wavelength band. On average, the absorption rate of the second sub-metal layer 514b of 1.75 Å/s is 54.4%, and the absorption rate of the first sub-metal layer 514a of 3.5 Å/s is 47.4%.

TABLE 5

| deposition | | | | | | | optical characteristics | | |
|---|---|---|---|---|---|---|---|---|---|
| rate | refractive index n | | | refractive index k | | | reflectance | transmittance | absorption |
| [Å/s] | 450 nm | 550 nm | 650 nm | 450 nm | 550 nm | 650 nm | [%] | [%] | rate [%] |
| 1.75 | 3.074 | 3.365 | 3.511 | 3.424 | 3.210 | 3.090 | 20.9 | 24.7 | 54.4 |
| 3.5 | 1.823 | 2.141 | 2.463 | 3.285 | 3.660 | 3.978 | 22.6 | 29.9 | 47.4 |

Table 6 below shows changes in the refractive index n and the refractive index k for each wavelength band according to the change in the deposition rate of the first sub-metal layer 514a.

As shown in Table 6, when the deposition rate of the first sub-metal layer 514a is in the range of 3.0 Å/s to 3.7 Å/s, and both the refractive index n and the refractive index k increase from the short wavelength band (450 nm) to the long wavelength band (650 nm).

In addition, it can be seen that when the deposition rate of the first sub-metal layer 514a increases from 3.0 Å/s to 3.7 Å/s, the refractive index n gradually decreases and the refractive index k gradually increases.

When the deposition rate of the first sub-metal layer 514a is in the range of 3.0 Å/s to 3.7 Å/s, it may be seen that the refractive index n of the short wavelength band (450 nm) is in the range of 2.055 to 1.758, the refractive index n of the medium wavelength band (550 nm) is in the range of 2.377 to 2.072, and the refractive index n of the long wavelength band (650 nm) is in the range of 2.690 to 2.389. In particular, when the deposition rate of the first sub-metal layer 514a increases from 3.0 Å/s to 3.7 Å/s, it may be seen that the refractive index n of the short wavelength band (450 nm) decreases from 2.055 to 1.758, the refractive index n of the medium wavelength band (550 nm) decreases from 2.377 to 2.072, and the refractive index n of the long wavelength band (650 nm) decreases from 2.690 to 2.389.

When the deposition rate of the first sub-metal layer 514a is in the range of 3.0 Å/s to 3.7 Å/s, it may be seen that the refractive index k of the short wavelength band (450 nm) is in the range of 3.150 to 3.379, the refractive index k of the medium wavelength band (550 nm) is in the range of 3.400 to 3.793, and the refractive index k of the long wavelength band (650 nm) is in the range of 3.650 to 4.125. In particular, when the deposition rate of the first sub-metal layer 514a increases from 3.0 Å/s to 3.7 Å/s, it may be seen that the refractive index k of the short wavelength band (450 nm) increases from 3.150 to 3.379, the refractive index k of the medium wavelength band (550 nm) increases from 3.400 to 3.793, and the refractive index k of the long wavelength band (650 nm) increases from 3.650 to 4.125.

As described above, as the deposition rate changes, the refractive index of the first sub-metal layer 514a changes for each wavelength band, and when the deposition rate of the first sub-metal layer 514a is in the range of 3.0 Å/s to 3.7 Å/s, it has an appropriate range of refractive index, so that the above-described low-reflection characteristics and color reproducibility characteristics can be implemented.

TABLE 6

| deposition | | | | | | |
|---|---|---|---|---|---|---|
| rate | refractive index n | | | refractive index k | | |
| [Å/s] | 450 nm | 550 nm | 650 nm | 450 nm | 550 nm | 650 nm |
| 3.0 Å/s | 2.055 | 2.377 | 2.690 | 3.150 | 3.400 | 3.650 |
| 3.1 Å/s | 2.000 | 2.322 | 2.640 | 3.166 | 3.443 | 3.711 |
| 3.2 Å/s | 1.950 | 2.271 | 2.592 | 3.187 | 3.491 | 3.774 |
| 3.3 Å/s | 1.904 | 2.224 | 2.547 | 3.214 | 3.543 | 3.840 |
| 3.4 Å/s | 1.861 | 2.181 | 2,504 | 3.247 | 3.599 | 3.907 |
| 3.5 Å/s | 1.823 | 2.141 | 2.463 | 3.285 | 3.660 | 3.978 |
| 3.6 Å/s | 1.789 | 2.105 | 2.425 | 3.329 | 3.724 | 4.050 |
| 3.7 A/s | 1.758 | 2.072 | 2.389 | 3.379 | 3.793 | 4.125 |

Table 7 below shows changes in the refractive index n and the refractive index k for each wavelength band according to the change in the deposition rate of the second sub-metal layer 514b.

As shown in Table 7, when the deposition rate of the second sub-metal layer 514b is in the range of 1.7 Å/s to 2.0 Å/s, and the refractive index n increases and the refractive index k decrease from the short wavelength band (450 nm) to the long wavelength band (650 nm).

In addition, it can be seen that when the deposition rate of the second sub-metal layer 514b increases from 1.7 Å/s to 2.0 Å/s, the refractive index n gradually decreases in an entire wavelength band. On the other hand, the refractive index k gradually decreases in the short wavelength band (450 nm) and the medium wavelength band (550 nm), but gradually increases in the long wavelength band (650 nm).

When the deposition rate of the second sub-metal layer 514b is in the range of 1.7 Å/s to 2.0 Å/s, it may be seen that the refractive index n of the short wavelength band (450 nm) is in the range of 3.128 to 2.820, the refractive index n of the medium wavelength band (550 nm) is in the range of 3.416 to 3.122, and the refractive index n of the long wavelength band (650 nm) is in the range of 3.551 to 3.318. In particular, when the deposition rate of the second sub-metal layer 514b increases from 1.7 Å/s to 2.0 Å/s, it may be seen that the refractive index n of the short wavelength band (450 nm) decreases from 3.128 to 2.820, the refractive index n of the medium wavelength band (550 nm) decreases from 3.416 to 3.122, and the refractive index n of the long wavelength band (650 nm) decreases from 3.551 to 3.318.

When the deposition rate of the second sub-metal layer 514b is in the range of 1.7 Å/s to 2.0 Å/s, it may be seen that the refractive index k of the short wavelength band (450 nm) is in the range of 3.453 to 3.299, the refractive index k of the medium wavelength band (550 nm) is in the range of 3.216 to 3.195, and the refractive index k of the long wavelength band (650 nm) is in the range of 3.076 to 3.173. In particular, when the deposition rate of the second sub-metal layer 514b increases from 1.7 Å/s to 2.0 Å/s, it may be seen that the refractive index k of the short wavelength band (450 nm) decrease from 3.453 to 3.299, the refractive index k of the medium wavelength band (550 nm) decrease from 3.216 to 3.195, and the refractive index k of the long wavelength band (650 nm) increases from 3.076 to 3.173.

As described above, as the deposition rate changes, the refractive index of the second sub-metal layer 514b changes for each wavelength band, and when the deposition rate of the second sub-metal layer 514b is in the range of 1.7 Å/s to 2.0 Å/s, it has an appropriate range of refractive index, so that the above-described low-reflection characteristics and color reproducibility characteristics can be implemented.

TABLE 7

| deposition | | | | | | |
|---|---|---|---|---|---|---|
| rate | refractive index n | | | refractive index k | | |
| [Å/s] | 450 nm | 550 nm | 650 nm | 450 nm | 550 nm | 650 nm |
| 1.7 Å/s | 3.128 | 3.416 | 3.551 | 3.453 | 3.216 | 3.076 |
| 1.8 Å/s | 3.021 | 3.315 | 3.471 | 3.396 | 3.205 | 3.106 |
| 1.9 Å/s | 2.918 | 3.216 | 3.393 | 3.345 | 3.198 | 3.138 |
| 2.0 Å/s | 2.820 | 3.122 | 3.318 | 3.299 | 3.195 | 3.173 |

That is, a refractive index n of the first sub-metal layer 514a may be different from a refractive index n of the second sub-metal layer 514b. A refractive index n of the first sub-metal layer 514a may be lower than a refractive index n of the second sub-metal layer 514b in an entire wavelength band.

According to the present disclosure, the following effects are achieved.

According to one or more embodiments of the present disclosure, color reproduction can be improved by including sub-pixels that emit cyan-colored light.

According to one or more embodiments of the present disclosure, the sub-pixel emitting cyan-colored light comprises a first sub-light emitting area emitting green light and a second sub-light emitting area emitting blue light, so that the desired cyan-colored light can be obtained by adjusting the area ratio of the first sub-light emitting area and the second sub-light emitting area.

According to one or more embodiments of the present disclosure, the sub-pixel emitting cyan-colored light includes a first sub-light emitting area emitting green light and a second sub-light emitting area emitting blue light, so that the desired cyan-colored light can be obtained by adjusting the thickness ratio of the green color filter provided in the first sub-light emitting area and the blue color filter provided in the second sub-light emitting area.

According to one or more embodiments of the present disclosure, by including a low-reflective electrode in the sub-pixel emitting cyan-colored light, the transmittance of the Transmittance Controllable Film (OTF) for anti-reflection can be improved, thereby improving the luminance.

According to one or more embodiments of the present disclosure, by including a first sub-metal layer formed at a relatively large deposition rate corresponding to a first sub-light emitting area and a second sub metal layer formed at a relatively small deposition rate corresponding to a second sub-light emitting area in a sub-pixel emitting cyan-colored light, the FWHM (Full Width at Half Maximum) of green light and blue light is reduced, thereby improving color reproduction.

As a result, according to one or more embodiments of the present disclosure, it is possible to realize a low-powered electroluminescent display device with high efficiency, low reflection, and high color reproduction.

Although the embodiments of the present disclosure have been described in more detail with reference to the accompanying drawings, the present disclosure is not necessarily limited to these embodiments, and may be variously modified without departing from the technical idea of the present disclosure. Therefore, the embodiments disclosed in the present disclosure are not intended to limit the technical idea of the present disclosure, but to explain, and the scope of the technical idea of the present disclosure is not limited by these embodiments. Therefore, it should be understood that the above-described embodiments are exemplary and not limited in all respects. The scope of protection of the present disclosure should be interpreted by the claims, and all technical ideas within the equivalent scope should be interpreted as being included in the scope of the present disclosure.

What is claimed is:

1. An electroluminescent display device, comprising:
a first sub-pixel including a first light emitting area;
a first electrode in the first sub-pixel;
a light emitting layer on the first electrode;
a second electrode on the light emitting layer;
an encapsulation layer on the second electrode, and
a cyan color filter on the encapsulation layer,
wherein the first light emitting area includes a first sub-light emitting area and a second sub-light emitting area,
the cyan color filter includes a first sub-color filter corresponding to the first sub-light emitting area and a second sub-color filter corresponding to the second sub-light emitting area, and
the first sub-color filter transmits a green light, and the second sub-color filter transmits a blue light.

2. The electroluminescent display device of claim 1, wherein an area of the first sub-light emitting area is larger than an area of the second sub-light emitting area.

3. The electroluminescent display device of claim 2, wherein a ratio of the area of the first sub-light emitting area to the area of the second sub-light emitting area is in a range of 7:3 to 9:1.

4. The electroluminescent display device of claim 1, wherein a thickness of the first sub-color filter is greater than a thickness of the second sub-color filter.

5. The electroluminescent display device of claim 4, wherein a ratio of the thickness of the first sub-color filter to the thickness of the second sub-color filter is in a range of 1.8:1 to 2:1.

6. The electroluminescent display device of claim 4, wherein a lower surface of the first sub-color filter is located closer to the second electrode than a lower surface of the second sub-color filter.

7. The electroluminescent display device of claim 4, wherein an upper surface of the first sub-color filter and an upper surface of the second sub-color filter are formed at the same height.

8. The electroluminescent display device of claim 1, wherein the first sub-color filter and the second sub-color filter are in contact with each other at a boundary between the first sub-light emitting area and the second sub-light emitting area.

9. The electroluminescent display device of claim 1, further comprising a second sub-light emitting area having a bar structure, and
the first sub-light emitting area is on one side of the second sub-light emitting area, or the first sub-light emitting area includes a first region and a second region spaced apart from each other with the second sub-light emitting area between the first region and the second region.

10. The electroluminescent display device of claim 1, wherein the first sub-light emitting area surrounds an entire outer periphery of a second sub-light emitting area of the electroluminescent display device.

11. The electroluminescent display device of claim 1, wherein the first electrode includes a first sub-metal layer corresponding to the first sub-light emitting area and a second sub-metal layer corresponding to the second sub-light emitting area, and a refractive index n of the first sub-metal layer is different from a refractive index n of the second sub-metal layer.

12. The electroluminescent display device of claim 11, wherein the first sub-metal layer and the second sub-metal layer include a same material, and a deposition rate of the first sub-metal layer is higher than a deposition rate of the second sub-metal layer.

13. The electroluminescent display device of claim 12, wherein the deposition rate of the first sub-metal layer is in a range of 3.0 Å/s to 3.7 Å/s, and the deposition rate of the second sub-metal layer is in a range of 1.7 Å/s to 2.0 Å/s.

14. The electroluminescent display device of claim 11, wherein a refractive index n of the first sub-metal layer is lower than a refractive index n of the second sub-metal layer in an entire wavelength band.

15. The electroluminescent display device of claim 11, wherein a refractive index n of the first sub-metal layer ranges from 1.758 to 2.055 in a wavelength band of 450 nm, and a refractive index n of the first sub-metal layer ranges from 2.072 to 2.377 in a wavelength band of 550 nm, and
a refractive index n of the second sub-metal layer ranges from 2.820 to 3.128 in the wavelength band of 450 nm, and a refractive index n of the second sub-metal layer ranges from 3.122 to 3.416 in the wavelength band of 550 nm.

16. The electroluminescent display device of claim 11, wherein the first electrode further includes:
a first transparent conductive layer;
a first metal layer on the first transparent conductive layer;
a second transparent conductive layer on the first metal layer; and
a third transparent conductive layer on the second transparent conductive layer, and
wherein the first sub-metal layer and the second sub-metal layer contact each other at a boundary between the first sub-light emitting area and the second sub-light emitting area, and the first sub-metal layer and the second sub-metal layer are between the second transparent conductive layer and the third transparent conductive layer.

17. The electroluminescent display device of claim 11, wherein the first sub-metal layer and the second sub-metal layer contact each other at a boundary between the first sub-light emitting area and the second sub-light emitting area.

18. An electroluminescent display device comprising:
a plurality of subpixels including a first sub-pixel having a first light emitting area and a second sub-pixel having a second light emitting area;
a first electrode in each of the first sub-pixel and the second sub-pixel;
a light emitting layer on the first electrode in each of the first sub-pixel and the second sub-pixel;
a second electrode on the light emitting layer; and
a plurality of color filters including a first color filter corresponding to the first light emitting area and a second color filter corresponding to the second light emitting area,
wherein the first light emitting area includes a first sub-light emitting area and a second sub-light emitting area, the first sub-light emitting area and the second sub-light emitting area emitting light of different colors, and
the first color filter includes a first sub-color filter corresponding to the first sub-light emitting area and a second sub-color filter corresponding to the second sub-light emitting area.

19. The electroluminescent display device of claim 18, wherein the first sub-pixel emits cyan light, and the second sub-pixel emits any one of red light, green light, or blue light, and
wherein the first sub-color filter includes a green color filter, and the second sub-color filter includes a blue color filter.

20. The electroluminescent display device of claim 18, wherein an area of the first sub-light emitting area is larger than an area of the second sub-light emitting area.

21. The electroluminescent display device of claim 18, wherein a thickness of the first sub-color filter is greater than a thickness of the second sub-color filter.

22. The electroluminescent display device of claim 21, wherein a thickness of the second color filter is thinner than the thickness of the first sub-color filter and is equal to or less than the thickness of the second sub-color filter.

23. The electroluminescent display device of claim 18, wherein a thickness of the first electrode of the first sub-pixel is greater than a thickness of the first electrode of the second sub-pixel.

24. The electroluminescent display device of claim 18, wherein the first electrode of the first sub-pixel includes a first sub-metal layer corresponding to the first sub-light emitting area and a second sub-metal layer corresponding to the second sub-light emitting area,
the first sub-metal layer and the second sub-metal layer include of a same material, and
a refractive index of the first sub-metal layer is different from a refractive index of the second sub-metal layer.

25. The electroluminescent display device of claim 18, wherein a reflectance of the first electrode of the first sub-pixel is lower than a reflectance of the first electrode of the second sub-pixel.
